(19) United States
(12) Patent Application Publication
(10) Pub. No.: US 2024/0105777 A1
(43) Pub. Date: Mar. 28, 2024

(54) 3D UFET DEVICES AND METHODS FOR MANUFACTURING THE SAME

(71) Applicant: Tokyo Electron Limited, Tokyo (JP)

(72) Inventors: H. Jim Fulford, Albany, NY (US); Mark I. Gardner, Albany, NY (US)

(73) Assignee: Tokyo Electron Limited, Tokyo (JP)

(21) Appl. No.: 17/950,866

(22) Filed: Sep. 22, 2022

(51) Int. Cl. H01L 29/10; H01L 29/40; H01L 29/66; H01L 29/78

(52) U.S. Cl. CPC H01L 29/1037; H01L 29/401; H01L 29/66795; H01L 29/7855

(57) ABSTRACT

Semiconductor devices and methods of manufacture are disclosed. The method includes forming a stack including a first pair of metal layers separated with a first dielectric layer and a second pair of metal layers separated with a second dielectric layer. The method includes separating the stack into a first portion of the first pair of metal layers and the first dielectric layer, a second portion of the first pair of metal layers and the first dielectric layer, a third portion of the second pair of metal layers and the second dielectric layer, and a fourth portion of the second pair of metal layers and the second dielectric layer. The method for fabricating semiconductor devices includes indenting, the first to fourth portions to form first to fourth recesses, respectively, and forming first to fourth transistors, respectively.

### FIELD OF THE DISCLOSURE

The present disclosure relates generally to non-planar, or three-dimensional (3D), transistors structures and methods for manufacture the same.

### BACKGROUND

In the manufacture of semiconductor devices, various fabrication processes are executed, such as film-forming depositions, etch mask creation, patterning, material etching and removal, and doping treatments. These processes may be performed to form semiconductor device components on a substrate. Some example fabrication techniques allow the manufacture of transistors on a single active device plane, while wiring or metallization is formed above the active device plane. Such devices are accordingly characterized as two-dimensional (2D) circuits, manufactured using 2D fabrication techniques. Although scaling efforts have greatly increased the number of transistors per unit area in 2D circuits, these 2D fabrication techniques are approaching physical atomic limitations with single digit nanometer semiconductor device fabrication nodes.

### SUMMARY

Three-dimensional (3D) integration, e.g., a stacking (or vertical arrangement) of multiple semiconductor devices (e.g., transistor structures), aims to overcome scaling limitations experienced in planar devices by increasing transistor density in volume rather than area.

The techniques described herein include methods and devices for 3D integration of semiconductor devices. Specifically, techniques may include self-aligned metal routing for vertical channel transistors achieved with 360-degree symmetry for 3D vertical transistors. Excellent compact circuit layout may be obtained with such techniques. Techniques herein can be used for any geometry device (i.e., circular, rectangular, ellipse).

In one aspect of the present disclosure, a method for fabricating semiconductor devices includes forming a first pair of metal layers separated from each other with a first dielectric layer. The method includes forming a first recess laterally extending into the first pair of metal layers and the first dielectric layer. The method includes forming a first transistor at the first recess.

In some embodiments, the method includes lining the first recess with a first channel material; and filling the first recess with a first gate structure.

In some embodiments, the method includes forming a second pair of metal layers separated from each other with a second dielectric layer, wherein the second pair of metal layers are disposed next to the first pair of metal layers; forming a third pair of metal layers separated from each other with a third dielectric layer, wherein the third pair of metal layers are disposed above the first pair of metal layers; and forming a fourth pair of metal layers separated from each other with a fourth dielectric layer, wherein the fourth pair of metal layers are disposed above the second pair of metal layers.

In some embodiments, the method includes forming a second recess laterally extending into the second pair of metal layers and the second dielectric layer; forming a third recess laterally extending into the third pair of metal layers and the third dielectric layer; forming a fourth recess laterally extending into the fourth pair of metal layers and the fourth dielectric layer; forming a second transistor at the second recess; forming a third transistor at the third recess; and forming a fourth transistor at the fourth recess.

In some embodiments, the method includes filling an opening between the first pair of metal layers and the second pair of metal layers and between the third pair of metal layers and the fourth pair of metal layers with a dielectric material to electrically isolate the first to fourth transistors from one another.

In some embodiments, the method includes lining the second recess with a second channel material; filling the second recess with a second gate structure; lining the third recess with a third channel material; filling the third recess with a third gate structure; lining the fourth recess with a fourth channel material; and filling the fourth recess with a fourth gate structure.

In some embodiments, each of the first to fourth channel materials includes a two-dimensional (2D) semiconductor material. In some embodiments, each of the first to fourth channel materials includes a semiconductor oxide material. In some embodiments, the first to fourth transistors have a same conductive type. In some embodiments, the first and second transistor have a first conductive type, while the third and fourth transistors have a second, opposite conductive type.

In another aspect of the present disclosure, a method for fabricating semiconductor devices includes exposing a first pair of metal layers separated from each other with a first dielectric layer and a second pair of metal layers separated from each other with a second dielectric layer, wherein the second pair of metal layers are laterally aligned with the first pair of metal layers, respectively. The method includes exposing a third pair of metal layers separated from each other with a third dielectric layer and a fourth pair of metal layers separated from each other with a fourth dielectric layer, wherein the fourth pair of metal layers are laterally aligned with the second pair of metal layers, respectively. The method includes removing exposed portions of the first pair of metal layers and the first dielectric layer and removing exposed portions of the second pair of metal layers and the second dielectric layer to form a first recess and a second recess, respectively. The method includes removing exposed portions of the third pair of metal layers and the third dielectric layer and removing exposed portions of the fourth pair of metal layers and the fourth dielectric layer to form a third recess and a fourth recess, respectively. The method includes forming a first transistor and a second transistor in the first and second recesses, respectively. The method includes forming a third transistor and a fourth transistor in the third and fourth recesses, respectively.

In some embodiments, the following steps of the method are concurrently performed: removing the exposed portions of the first pair of the metal layers and the first dielectric layer and removing the exposed portions of the second pair of the metal layers and the second dielectric layer to form the first recess and the second recess, respectively; and removing exposed portions of the third pair of the metal layers and the third dielectric layer and removing the exposed portions of the fourth pair of the metal layers and the fourth dielectric layer to form the third recess and the fourth recess, respectively.

In some embodiments, the following steps of the method are concurrently performed: forming the first transistor and the second transistor in the first and second recesses, respectively; and forming the third transistor and the fourth transistor in the third and fourth recesses, respectively. In some embodiments, the first to fourth transistors have a same conductive type.

In some embodiments, the following step of the method: forming the first transistor and the second transistor in the first and second recesses, respectively, is performed after the following step: removing the exposed portions of the first pair of the metal layers and the first dielectric layer and removing the exposed portions of the second pair of the metal layers and the second dielectric layer to form the first recess and the second recess, respectively.

In some embodiments, the following step of the method: forming the third transistor and the fourth transistor in the third and fourth recesses, respectively, is performed after the following step: removing the exposed portions of the third pair of the metal layers and the third dielectric layer and removing the exposed portions of the fourth pair of the metal layers and the fourth dielectric layer to form the third recess and the fourth recess, respectively. In some embodiments, the first and second transistors have a first conductive type, and the third and fourth transistors have a second, opposite conductive type.

In some embodiments, the step of forming the first transistor and the second transistor in the first and second recesses, respectively, includes forming a first channel material and a second channel material in the first recess and the second recess, respectively; and forming a first gate structure and a second gate structure in contact with vertically extending portions of the first channel material and the second channel material, respectively.

In some embodiments, the step of forming the third transistor and the fourth transistor in the third and fourth recesses, respectively, includes forming a third channel material and a fourth channel material in the third recess and the fourth recess, respectively; and forming a third gate structure and a fourth gate structure in contact with vertically extending of the third channel material and the fourth channel material, respectively.

In some embodiments, each of the first to fourth channel materials includes a two-dimensional (2D) semiconductor material. In some embodiments, each of the first to fourth channel materials includes a semiconductor oxide material.

In yet another aspect, a semiconductor device includes a pair of metal layers separated from each other with a dielectric layer; a channel material vertically extending and having a first side in contact with the pair of metal layers; and a gate structure vertically extending and in contact with a second side of the channel material.

In some embodiments, the semiconductor device includes a device isolation vertically extending and in contact with the gate structure.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 is a flow chart of an example method for making a semiconductor device, in accordance with some embodiments.

FIGS. 2-10 each illustrate a cross-sectional view of a semiconductor device, during one of various fabrication stages, made by the method of FIG. 1, in accordance with some embodiments.

FIG. 11 is a flow chart of an example method for making a semiconductor device, in accordance with some embodiments.

FIGS. 12-19 each illustrate a cross-sectional view of a semiconductor device, during one of various fabrication stages, made by the method of FIG. 11, in accordance with some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Disclosed herein are embodiments related to one or more transistor structures based on a metal spine U-shaped field-effect transistor (UFET) structure that is compatible with conductive semiconductor oxides and/or two-dimensional (2D) materials. In some embodiments, the metal spine UFET structure may be formed of a number of layers that can facilitate top three-dimensional (3D) connections of these transistors with S/D rails adjacent to the conductive oxide and/or 2D material.

Reference will now be made to the figures, which for the convenience of visualizing the 3D fabrication techniques described herein, illustrate a substrate undergoing a process flow in both top and cross-sectional views. Unless expressly indicated otherwise, each Figure represents one (or a set) of fabrication steps in a process flow for manufacturing the devices described herein. In the top and cross-sectional views of the Figures, connections between conductive layers or materials may be shown. However, it should be understood that these connections between various layers and masks are merely illustrative, and are intended to show a capability for providing such connections and should not be considered limiting to the scope of the claims.

Likewise, although the Figures and aspects of the disclosure may show or describe devices herein as having a particular shape, it should be understood that such shapes are merely illustrative and should not be considered limiting to the scope of the techniques described herein. For example, the techniques described herein may be implemented in any shape or geometry for any material or layer to achieve desired results. In addition, examples in which two transistors or devices are shown stacked on top of one another are shown for illustrative purposes only, and for the purposes of simplicity. Indeed, the techniques described herein may provide for one to any number of stacked devices. Further, although the devices fabricated using these techniques are shown as transistors, it should be understood that any type of electric electronic device may be manufactured using such techniques, including but not limited to transistors, variable resistors, resistors, and capacitors.

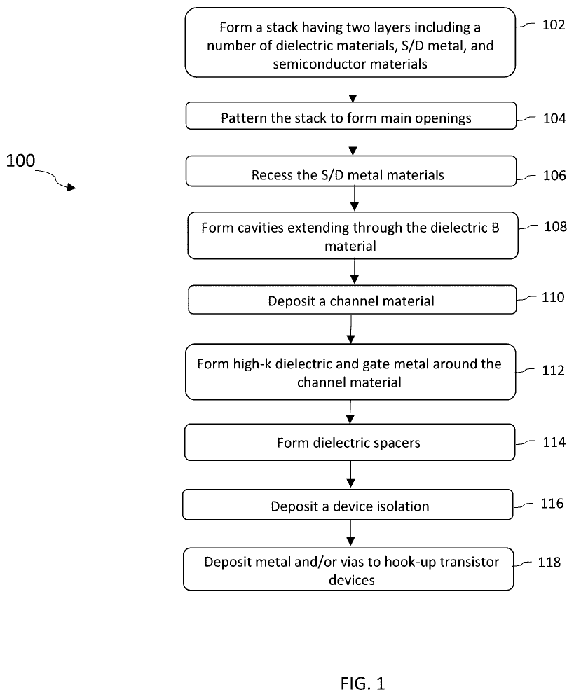

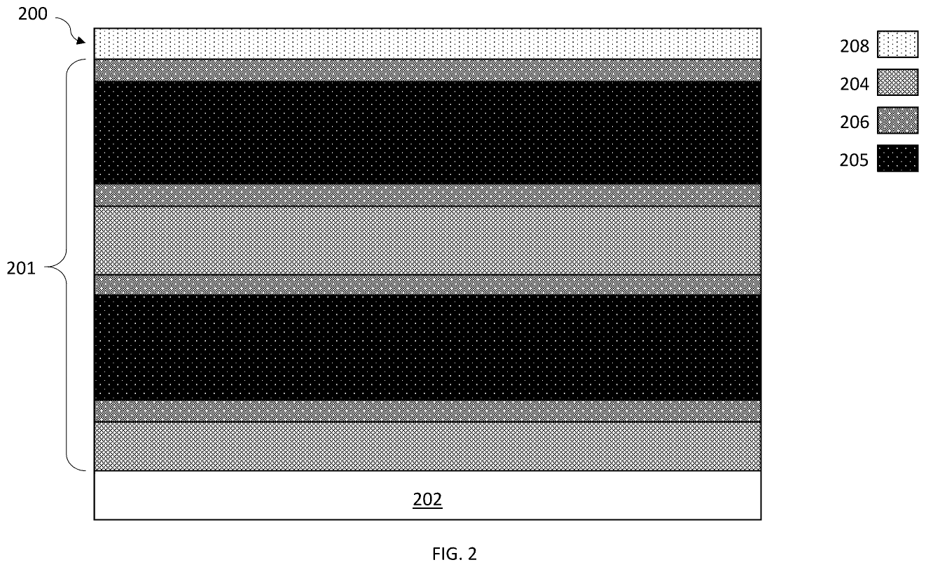

FIG. 1 illustrates a flowchart of an example method 100 for forming a semiconductor device including a number of U-shaped Field-Effect-Transistors (UFETs). For example, each UFET can include a vertically extending channel, with a portion of the channel in contact with a gate structure. The vertical channel can have its end portions in contact with a pair of horizontally extending dielectric spacers that vertically sandwich the gate structure. As such, the horizontal dielectric spacers, together with the vertical channel, can form a rotated U-shape. In various embodiments, operations of the method 100 may be associated with cross-sectional views of an example semiconductor device 200 including a number of such UFETs at various fabrication stages as shown in FIGS. 2 to 10, which will be discussed in further detail below.

In brief overview, the method 100 starts with operation 102 of forming a stack having at least two main layers each including a number of dielectric materials, S/D metal, and semiconductor materials. The method 100 proceeds to operation 104 of patterning the stack. The method 100 proceeds to operation 106 of recessing the S/D metal materials. The method 100 proceeds to operation 108 of forming recesses extending through the dielectric B material. The method 100 proceeds to operation 110 of depositing a channel material. The method 100 proceeds to operation 112 of forming high-k dielectric and gate metal around the channel material. The method 100 proceeds to operation 114 of forming dielectric spacers. The method 100 proceeds to operation 116 of depositing a dielectric isolation. The method 100 proceeds to operation 118 of depositing metal and/or vias to hook-up transistor devices.

Corresponding to operation 102 of FIG. 1, FIG. 2 is a cross-sectional view of the semiconductor device 200 in which a stack 201 is formed on a substrate 202, at one of the various stages of fabrication, in accordance with various embodiments.

As shown, the stack 201, formed on the substrate 202, includes a number of dielectric materials of at least two different types: dielectric A generally denoted 204 and dielectric B generally denoted 205. Also, the stack 201 includes a number of source/drain (S/D) materials 206 wherein each layer of the stack 201 includes the dielectric B 205 sandwiched between two S/D metal materials 206 and stacked on top of the dielectric A 204. Additionally, the stack 201 may be overlaid by a cap layer 208. Although the stack 201 has two layers each consisting of one dielectric A material 204, one dielectric B material 205 and two S/D metal materials 206 in the illustrated embodiment of FIG. 2, it should be understood that the stack 201 can include any number of dielectric A and B materials (204 and 205, respectively) and any number of S/D metal materials 206 alternately stacked, while remaining within the scope of present disclosure.

In various embodiments, the dielectric A and B materials (204 and 205, respectively) can have an etching selectively with respect to one or more other materials formed next to itself, allowing the dielectric material to be selectively removed while keeping the adjacent materials substantially intact (which will be discussed in further detail below).

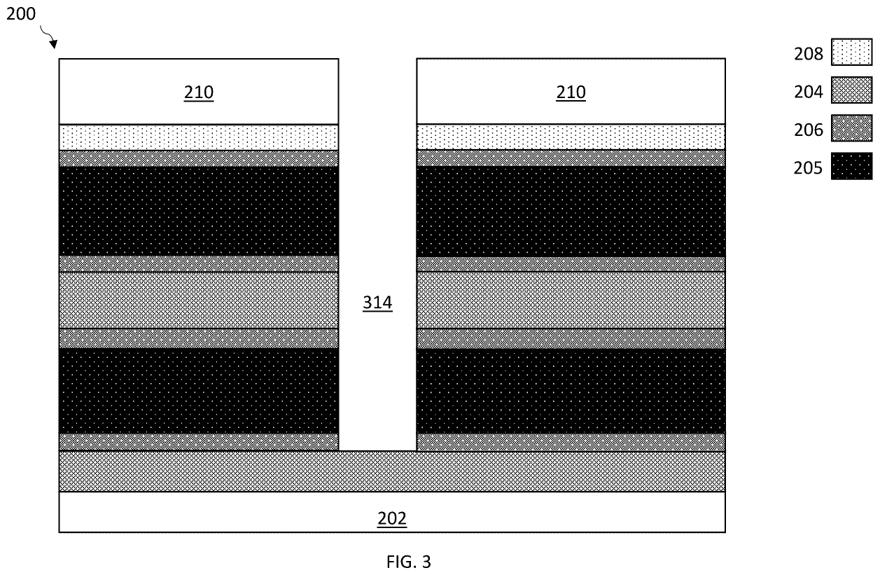

Corresponding to operation 104 of FIG. 1, FIG. 3 is a cross-sectional view of the semiconductor device 200 in which the stack 201 is patterned, at one of the various stages of fabrication, in accordance with various embodiments.

The stack 201 may be patterned by performing at least one of the following processes: (1) forming a (e.g., photoresist) mask 210 on the stack 201; (2) etching the stack 201 to define a width and length of the dielectric A material 204 using the mask 210; and (3) removing the mask 210. In some embodiments, the mask 210 may be formed on the cap layer 208. In some embodiments, the etching may be anisotropic (e.g., vertically applied over the workpiece), which allows the (patterned) stack 201 to have its sidewalls substantially aligned with the mask 210. In various embodiments, the removed portions of the stack 201, which exposes ends of each of the dielectric A and B materials (204 and 205, respectively) as well as the S/D metal material 206, can define a main opening 314, as shown.

More specifically, one or more masks can be formed above the mask material using at least one suitable masking technique. Once the masks are formed, one or more etch techniques may be performed to remove the portion of the underlying materials aligned with the opening in the mask (e.g., portions of underlying materials not covered with the mask). Any type of suitable etching techniques may be used, including but not limited to dry etching, wet etching, or plasma etching techniques. The mask may be removed once the etching process to remove a portion of the materials is completed. Hereinafter, to remove one or more described materials, one or more masks and etching techniques can be used as discussed above. The etching process can remove materials in any geometry, such as vertically or diagonally. The dimension (e.g., width or diameter) of the masks can correspond to the dimension of the opening (e.g., removed portions of the materials) or the dimension of the underlying materials of the masks.

Following the formation of the hardmask layer (not shown), a patternable layer (e.g., a photoresist mask 210) with patterns is formed over the hardmask layer. Next, at least one dry etching or a wet etching process including, e.g., dilute hydrofluoric (DHF) acid, may be performed to etch the dielectric B material 205, the S/D materials 206, and one of the layers of the dielectric A material 204 that is disposed between the S/D materials 206. Such etching is done until another layer of the dielectric A material 204 (that is disposed above the substrate 202 material) is exposed so as to form the main opening 314. Further, the main openings 314 can be formed with any of various cross-section profiles. For example, each of the main openings 314 can have a square, triangular, circular, elliptical, or any other cross-section, which will be shown below.

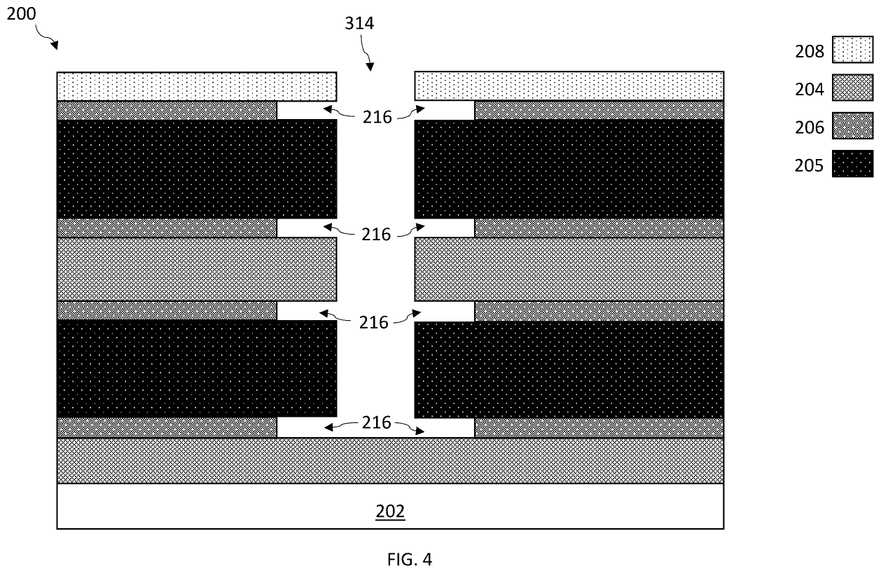

Corresponding to operation 106 of FIG. 1, FIG. 4 is a cross-sectional view of the semiconductor device 200 in which a plurality of recesses 216 are formed in respective ends of the S/D metal material 206, at one of the various stages of fabrication, in accordance with various embodiments.

The recesses 216 can be formed at least by etching the S/D metal material 206. The etching may be isotropic, anisotropic, or combinations thereof. Specifically, the etching may include applying etchants on exposed sidewalls of the dielectric A and B materials (204 and 205, respectively) and the S/D metal materials 206, while the etchants may induce a limited etching amount on the exposed sidewalls of the dielectric A and B materials (204 and 205, respectively). As such, the S/D metal materials 206 may each be inwardly indented on each end with a certain distance. Such a distance can be controlled according to a time duration of the etching process, for example.

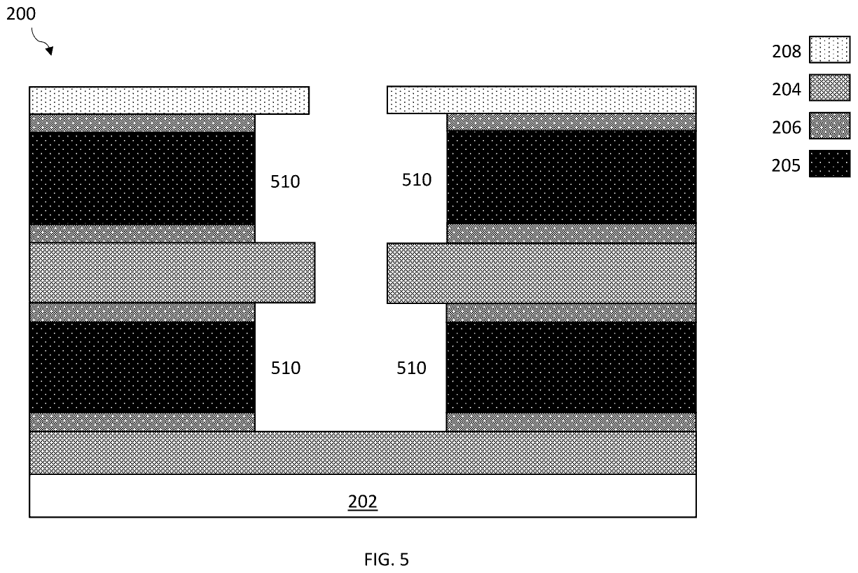

Corresponding to operation 108 of FIG. 1, FIG. 5 is a cross-sectional view of the semiconductor device 200 in which a plurality of recesses 510 are formed in respective ends of the dielectric B material 205, at one of the various stages of fabrication, in accordance with various embodiments.

The recesses 510 can be formed at least by etching the dielectric B material 205. The etching may be isotropic, anisotropic, or combinations thereof. Specifically, the etching may include applying etchants on exposed sidewalls of the dielectric A and B materials (204 and 205, respectively) and the S/D metal materials 206, while the etchants may induce a limited etching amount on the exposed regions of the dielectric A material 204 and the S/D metal materials 206. As such, regions of the dielectric B material 205 may each be inwardly indented on each end with a certain distance. Such a distance can be controlled according to a time duration of the etching process, for example. In some embodiments, the dielectric B material 205 and the S/D metal materials 206 are etched such that the respective ends of the S/D metal materials 206 are aligned with the ends of the dielectric B material 205 sandwiched between the respective layers of the S/D metal materials 206. In some embodiments, the dielectric A material 204 extend beyond the ends of the dielectric B material 205 and the S/D metal materials 206. Therefore, the resultant recesses 510 resemble the U-shape lending to the device name—a UFET device.

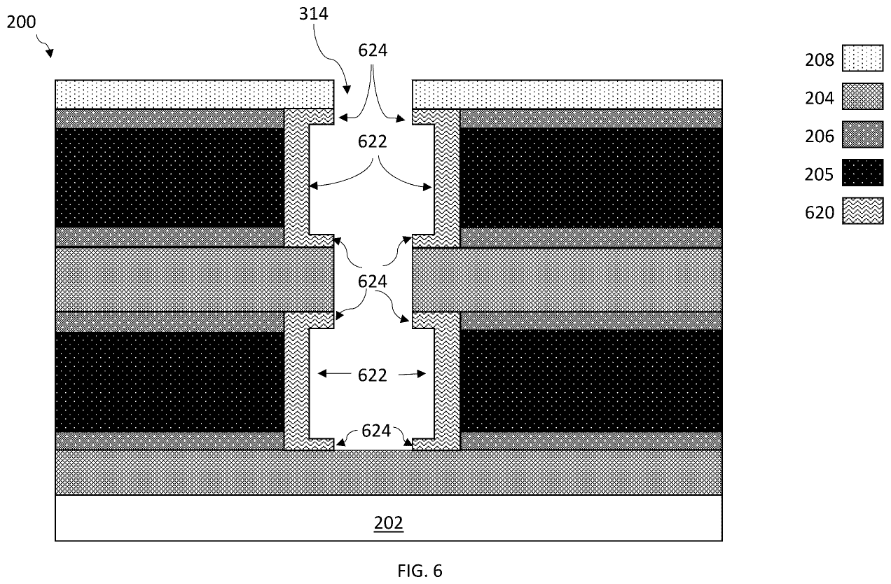

Corresponding to operation 110 of FIG. 1, FIG. 6 is a cross-sectional view of the semiconductor device 200 in which a channel material 620 is formed (e.g., deposited) within each of the recesses 510 (FIG. 5), at one of the various stages of fabrication, in accordance with various embodiments.

In some embodiments, the channel material 602 may include one or more semiconductive-behaving materials (e.g., conductive oxide materials), which may be formed using certain elements that, when combined with oxygen, form a new material that exhibits semiconductive behaviors. For example, the semiconductive-behaving material can be “turned off” and can have a low or practically no off-state leakage current, and the semiconductive-behaving material can be “turned on” and become highly conductive when voltage is applied. Example semiconductive-behaving materials to create an n-type channel for example include, but are not limited to, In₂O₃, SnO₂, In GaZnO, and ZnO. Example semiconductive-behaving materials that can be used to create a p-type channel may be formed utilizing, for example, SnO. These materials may be further doped to improve the electrical characteristics. These materials may also be referred to as conductive oxides, semiconductor oxides, or semiconductive-behaving oxides for the purposes of this discussion.

In some other embodiments, the channel material 602 may include one or more 2D materials. The 2D material can refer to crystalline solids consisting of a single layer of atoms. The single layer of atoms can be derived from single elements or multiple elements. Such 2D materials can include, for example, but are not limited to, WS2, WSe2, WTe2, MoS2, MoSe2, MoTe2, HfS2, ZrS2, and TiS2, GaSe, InSe, phosphorene, and other similar materials.

The 2D material and/or conductive oxide can function as a channel of the semiconductor device 200 or a portion of the channel. In some embodiments, the channel material 620, that includes one or more of the above-listed conductive oxides, can form a channel region of a conductive oxide-based transistor. For example, the lower and upper layers of the conductive oxides 620 can form channel regions of separate transistors or a same dual-channel (e.g., dual-nanosheet) transistor. semiconductor oxide

In some embodiments, the formation methods of the channel material 620 may include molecular beam deposition (MBD), atomic layer deposition (ALD), plasma-enhanced chemical vapor deposition (PECVD), chemical vapor deposition (CVD), physical vapor deposition (PVD), and the like. The channel material 620 may be annealed during or after the device formation process to recrystallize or grow the crystals and thereby improve electrical characteristics. The channel material semiconductor oxide 620 may be annealed during or after the device formation process to recrystallize or grow the crystals and thereby improve electrical characteristics.

In some embodiments, the channel material 620 may each have at least a longitudinal portion 622 in contact with the dielectric B material 205 and a pair of the S/D metal materials 206. The channel material 620 may further have one or more transverse portions 624 extending from the longitudinal portion 622 away from the S/D metal material 206 and toward the main opening 314. Stated another way, the corresponding pair of S/D metal material 206 and the transverse portions 624 may extend away from the longitudinal portion 622 in opposite lateral directions. In some embodiments, the channel material 620 is etched such that each of the transverse ends of the channel material 620 is aligned with the respective ends of the cap layer material 208 spaced apart by the main opening 314.

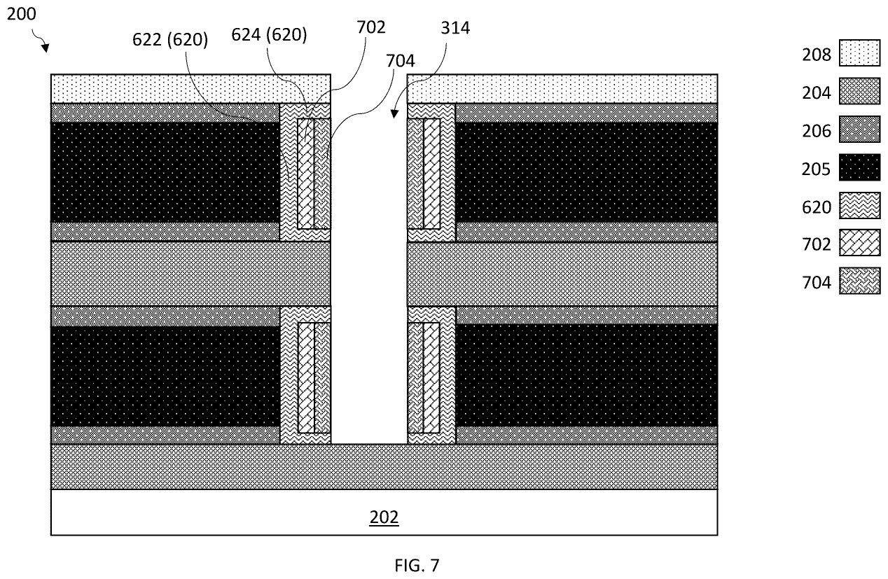

Corresponding to operation 112 of FIG. 1, FIG. 7 is a cross-sectional view of the semiconductor device 200 in which a high-k dielectric material 702 and a gate metal 704 are formed around each of the longitudinal portion 622 (of the 2D material or conductive oxide 620) that defines a channel region, at one of the various stages of fabrication, in accordance with various embodiments. In various embodiments, the high-k dielectric 702 and gate metal 704 can be collectively referred to as a gate structure.

In the illustrated embodiment of FIG. 7, the longitudinal portion 622 defining the channel region of 2D material or conductive oxide 620 wraps around the full perimeter of edges/ends of each of the S/D metal materials 206 (with a layer of the dielectric B material 205 interposed therebetween); further, the high-k dielectric material 702 wraps around the channel region of 2D material or conductive oxide 620, and the gate metal 704 wraps around the high-k dielectric 702.

The high-k dielectric 702 can be any type of material that has a relatively large dielectric constant. As one example, a silicon oxide-based gate dielectric such as silicon dioxide (SiO₂) may be selectively formed on a gate layer of silicon. Additionally or alternatively, other gate dielectric materials may be utilized such as silicon oxynitride (SiOₓN_{y}), silicon nitride (Si₃N₄), alumina (Al₂O₃), lanthanum oxide (La₂O₃), zirconium oxide (ZrO₂), hafnium oxide (HfO₂), hafnium zirconium oxide (HfZrO), tantalum oxide (Ta₂O₅), hafnium silicon oxide (HfSiO₄), zirconium silicon oxide (ZrSi0₄), titanium oxide (TiO₂), strontium titanium oxide (SrTiO₃), hafnium silicon oxynitride (HfSiOₓN_{y}), zirconium silicon oxynitride (ZrSiOₓN_{y}), hafnium oxynitride (HfOₓN_{y}), zirconium oxynitride (ZrOₓN_{y}), other suitable materials and combinations thereof.

In some embodiments, various techniques may be implemented to form the high-k gate 702 between the semiconductor (e.g., channel) region and the gate electrode 704. The formation methods of high-k dielectric 702 may include molecular beam deposition (MBD), ALD, PECVD, and the like. In some embodiments a selective deposition of a high-k dielectric may be utilized to form the transistor gates. In some implementations, a gate-recessing technique is utilized to allow a more uniform layer of doped conductive oxide material to form along the sidewall of the opening defined by the longitudinal and transverse portions 622 and 624 of the channel material 620. Another similar technique provides a non-selective deposition of the high-k dielectric in the gate-recessed opening in conjunction with self-aligned directional etching. These techniques may also be implemented to fabricate stacked transistors of the same type by utilizing the same conductive oxide for two or more transistor layers. These and other aspects are described in further detail herein.

Further, the high-k dielectric 702 may be formed by performing at least some of the following processes: filling the main openings 314 with the high-k gate material 702 and partially removing the high-k gate material 702 to form such structure of the high-k gate 702 so as to wrap around the channel region defined by longitudinal portion 622 (of the channel material 620) and the edges of the regions of the S/D material 206 with the high-k gate material 702.

For example, a patternable layer (e.g., a photoresist mask) can be formed over the workpiece, e.g., with the hardmask layer disposed above a portion of the high-k gate material 702 and the vertical structures disposed therewithin wherein the vertical structures include the S/D metal 206 and dielectric A and B materials 204 and 205, respectively. Further, the patternable layer can have a pattern (e.g., one or more openings) overlaying a portion of dielectric A material 204 and each of the pair of the S/D metal 206 and dielectric B material 205 disposed therewithin as well as portions of the high-k gate material 702 wrapping around the channel region 622 and the edges of the respective regions of the S/D material 206. By performing at least one etching process with the patternable layer as a mask, one or more openings can be formed such that each of the pair of the S/D metal 206 layers and dielectric B material 205 disposed therewithin is wrapped with the high-k gate material 702. Following the deposition of the high-k gate material 702, an etching process may be performed to remove excessive high-k gate material 702.

The gate metal 704 may include a p-type work function layer, an n-type work function layer, multi-layers thereof, or combinations thereof, in some embodiments. Accordingly, the gate metal is sometimes referred to as a work function layer or work function metal. Example p-type work function metals that may be included in the gate structures for p-type devices include TiN, TaN, Ru, Mo, Al, WN, ZrSi₂, MoSi₂, TaSi₂, NiSi₂, WN, other suitable p-type work function materials, or combinations thereof. Example n-type work function metals that may be included in the gate structures for n-type devices include Ti, Ag, TaAl, TaAlC, TiAlN, TaC, TaCN, TaSiN, Mn, Zr, other suitable n-type work function materials, or combinations thereof.

The work function layer(s) may be deposited by CVD, physical vapor deposition (PVD), ALD, and/or other suitable process. The gate metal 704 may be formed by performing at least some of the following processes: (1) filling regions between high-k gate material 702 and the transverse portions 624 of the channel material 620 (FIG. 6) with a gate metal material; and (2) performing a chemical mechanical polishing (CMP) process to remove excessive gate metal material until the cap layer 208 and the ends of transverse portions 624 of the channel material 620 are aligned with the gate metal material.

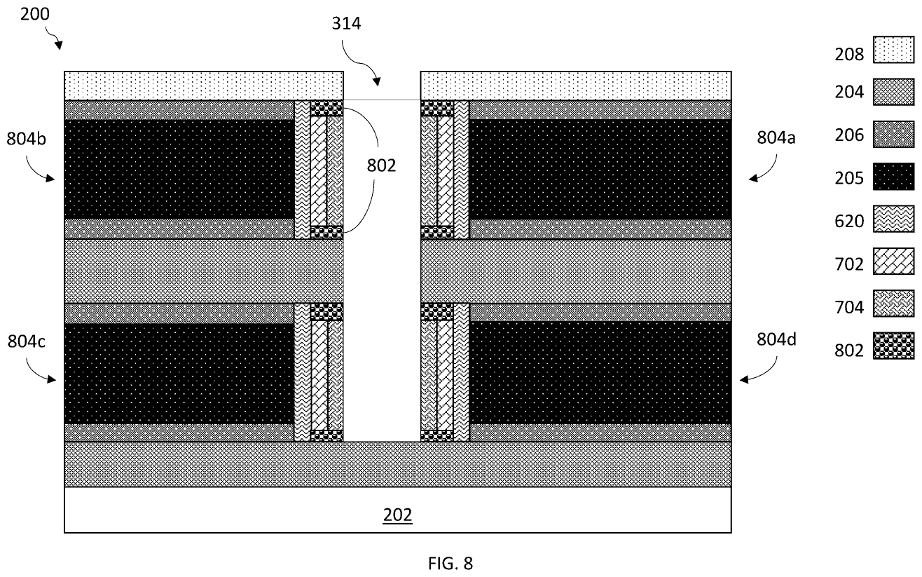

Corresponding to operation 114 of FIG. 1, FIG. 8 is a cross-sectional view of the semiconductor device 200 including a number of pairs of dielectric spacers 802 formed of a dielectric C material, at one of the various stages of fabrication, in accordance with various embodiments.

A pair of recesses (not shown) are formed on ends or edges of the longitudinal portion 622 by removing at least a substantial amount of the transverse portions 624, respectively. The recesses can be formed at least by etching the transverse portions 624 through the main opening 314. The etching may be isotropic, anisotropic, or combinations thereof. Specifically, the etching may include applying etchants on exposed sidewalls of the gate metal 704, the high-k material 702, the dielectric A material 204, the cap layer material 208, and the transverse portions 624 of the channel material 620, while the etchants may induce a limited etching amount on the gate metal 704, the high-k material 702, the dielectric A material 204, and the cap layer material 208. As such, the transverse portions 624 of the channel material 620 may be inwardly indented on each end/edge with a certain distance. Such a distance can be controlled according to a time duration of the etching process, for example.

Next, according to some embodiments, the dielectric C material may fill up the etched indents (recesses) to form the dielectric spacers (or shells) 802. In some embodiments, the dielectric spacers 802 are configured to reduce coupling between the gate electrode 704 and the S/D metal material 206, thereby reducing parasitic capacitance induced therebetween. The dielectric C material may be an oxide, such as a silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof.

In some embodiments, the dielectric C material may be formed by performing at least some of the following processes: filling the main opening 314 with the dielectric C material and partially removing the dielectric C material forming such structure where the dielectric C material fills the recess (that was formed by etching the transverse sides 624 of the channel material 620) between exposed edges of the longitudinal gate metal 704 as well as the high-k dielectric material 702, the cap layer 208 and the channel material 620.

For example, a patternable layer (e.g., a photoresist mask) can be formed over the workpiece, e.g., with the hardmask layer disposed above the dielectric C material. Further, the patternable layer can have a pattern (e.g., one or more openings) overlaying portions of the dielectric C material filling the main opening 314. By performing at least one etching process with the patternable layer as a mask, one or more openings can be formed, which can expose a portion of a sidewall of the dielectric C material that fills the recess between exposed edges of the longitudinal gate metal 704 as well as the high-k dielectric material 702, the cap layer 208 and the channel material 620. Following the deposition of the dielectric C material, an etching process may be performed to remove excessive dielectric C material. Other insulation materials and/or other formation processes may be used for forming the dielectric C material.

In some embodiments, upon forming the dielectric spacers 802, a number of transistor structures 804a, 804b, 804c, and 804d can be formed. Each of the transistors 804a to 804d includes a pair of the S/D materials 206 separated by a corresponding dielectric B material 205 layer, a corresponding high-k dielectric material 702, a corresponding gate metal 704, a corresponding pair of dielectric spacers 802, and a corresponding longitudinal portion 622 that functions as the transistor channel.

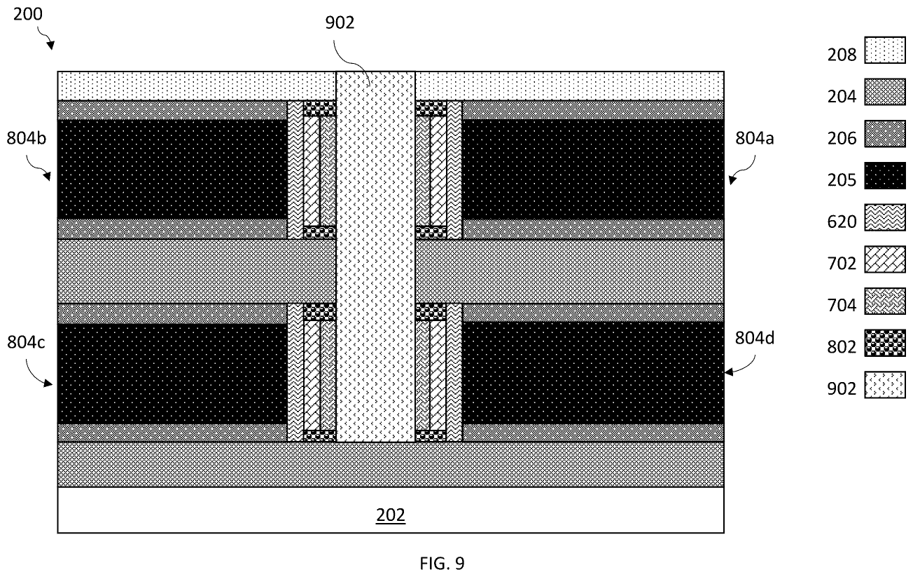

Corresponding to operation 116 of FIG. 1, FIG. 9 is a cross-sectional view of the semiconductor device 200 in which the main opening 314 are filled with a device isolation 902 formed of a dielectric D material, in accordance with various embodiments.

The device isolation 902 is configured to electrically isolate the gate metals 704 of the corresponding transistor structures 804a-d. The dielectric D material may include at least one insulation material, which can electrically isolate neighboring active structures (e.g., metal electrodes which are formed above) from each other. The insulation material may be an oxide, such as a silicon oxide, a nitride, the like, or combinations thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other insulation materials and/or other formation processes may be used. An anneal process may be performed once the insulation material is formed. In some embodiments, the dielectric D material may be formed by performing at least filling the main openings 314 with the dielectric D material. Following the deposition of the dielectric D material, an etching process may be performed to remove excessive dielectric material. Also, to complete the formation of the semiconductor device 200 after etching, the CMP can be performed to clean the top surface.

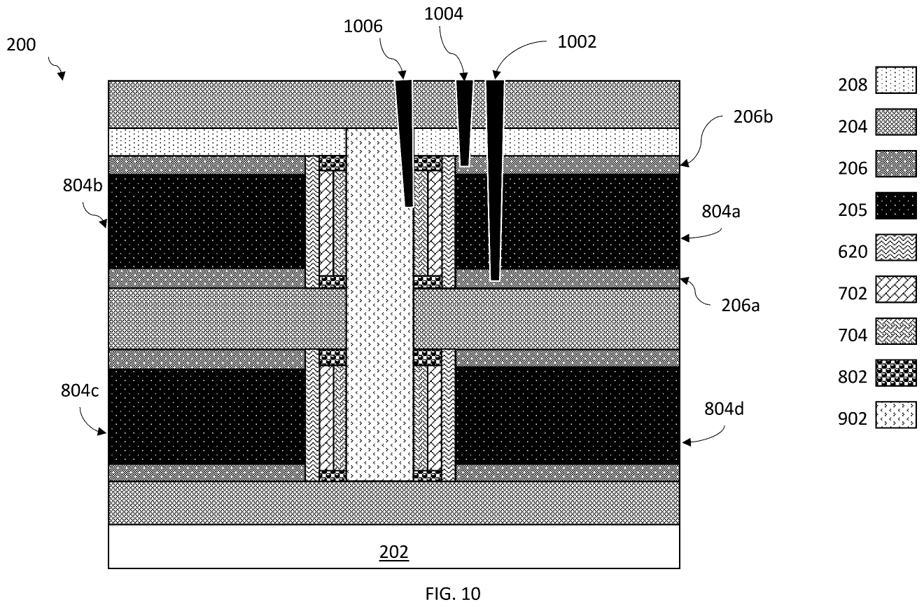

Corresponding to operation 118 of FIG. 1, FIG. 10 is a cross-sectional view of the semiconductor device 200 including a number of contacts 1002, 1004, 1006, in accordance with various embodiments.

For example, source/drain (S/D) contact 1002/1004 can route at least one of the S/D regions 206 for (e.g., electrical and/or physical) connection above the transistor structures 804a-d. The S/D contact 1002/1004 can be formed with one or more metal materials deposited using at least one suitable deposition technique. These S/D contacts 1002/1004 can be used to hookup the semiconductor device to a power source, for example. Similarly, gate contact 1006 can route at least one of the corresponding gate metal 704 for (e.g., electrical and/or physical) connection above the transistor structures 804a-d.

In some embodiments, the contacts 1002, 1004, and 1006 each include a conductive layer comprising any suitable conductive material, such as Cu, Al, W, Ru, other suitable materials, or combinations thereof. In some embodiments, the contacts 1002, 1004, and 1006 each include the conductive layer over a barrier layer, which may include Ti, Ta, TiN, TaN, other suitable materials, or combinations thereof.

For example, various openings for the contacts 1002, 1004, and 1006 can be formed similarly as illustrated in FIG. 10, such as using at least one suitable masking technique and etching technique. As shown, an additional layer of the dielectric A material 204 can be deposited over the semiconductor device. Openings can be formed extending from the surface of the dielectric A material 204 above the semiconductor device to a portion of the surface of the S/D regions and gate structures.

For example, the openings can extend to the surface of the base S/D region (e.g., bottom metal material 206a) and the top S/D region (e.g., top metal material 206b) of the first transistor structure 804a. The openings can further extend to the surface of the gate structures, e.g., the gate electrode 704 of the respective transistor device 804a. Through the openings, metal materials (e.g., shown as the contact 1002, 1004, and/or 1006) can be deposited in the openings using at least one suitable deposition technique. Upon the deposition, the S/D regions 206 and/or gate electrodes 704 can be (e.g., electrically) routed vertically, extending above the transistor devices 804a-d.

In the depicted embodiments, the interconnect structures, e.g., the contacts 1002, 1004, and 1006 are at least partially embedded in the dielectric A layer 204. As shown in FIG. 10, the dielectric A layer 204 can be around or surround the sidewall of the vias 1002, 1004, and 1006. The dielectric A layer 204 may expose the top surface of the contacts 1002, 1004, and 1006. The dielectric A layer 204 may extend at least along sidewalls of the contacts 1002, 1004, and 1006. The top surface of the contacts 1002, 1004, and 1006 may be substantially even or slightly recessed with respect to a plane of the top surface of the dielectric A layer 204. The contacts 1002, 1004, and 1006 may be formed in any suitable process, such as one or more damascene processes. An additional layer of the dielectric A material 204 can be deposited above the semiconductor device.

The other transistor devices 804b, 804c, and 804d may be coupled similarly, as described with respect to the transistor device 804a. The semiconductor devices 200 can be fabricated using the common source and any type of the individual electrically couplings to separate sources for regions of the S/D metal 206 and the gate electrode 704 of the individual transistor structures 804 may be implemented. Although the semiconductor devices 200 fabricated using the vertical interconnect structures such as the contacts 1002, 1004, and 1006 as illustrated in FIG. 10, it should be understood that any type of the individual electrically couplings to separate or combine sources for the regions of the S/D metal 206 and the gate electrode 704 of the individual transistor structures 804 may be implemented. In some embodiments, for example, one or more of the contacts 1006, 1004, and/or 1006 may extend to more than one transistor structure 804, for example, to 804a and 804d, or to some other transistor structures (such as 804b and/or 804c) or all of the transistor structures 804a through 804d. For example, in some embodiments, the interconnect structures may be fabricated such that the contacts 1002, 1004, and 1006 may be coupled to the transistor structures 804 such that contacts 1002, 1004, and/or 1006 go in and/or out of the page to connect to the source. Also, the semiconductor devices 200 using a combination of individual and common source layouts may be fabricated.

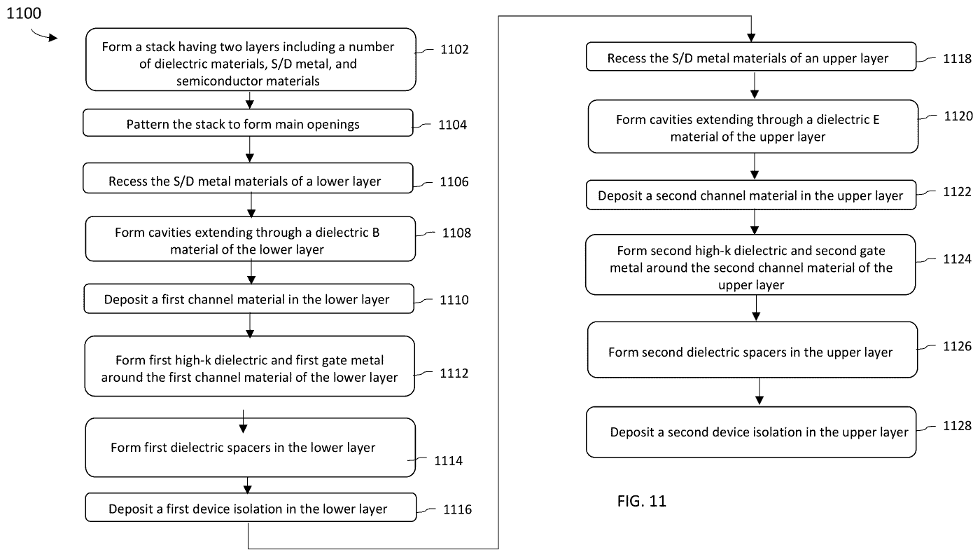

Reference is now made to FIG. 11 that illustrates a flowchart of an example method 1100 for forming another semiconductor device (e.g., two different conductive types of transistors stacked on top of one another), each of the transistors having at least a 2D material and/or conductive oxide that operatively serves as its channel. It is noted that the method 1100 is merely an example, and is not intended to limit the present disclosure. Accordingly, it is understood that additional operations may be provided before, during, and after the method 1100 of FIG. 11, and that some other operations may only be briefly described herein.

More specifically, FIG. 11 illustrates a flowchart of an example method 1100 for forming two layers of transistor structures where each layer has a different conductive type than the other layer. For example, one or more PMOS (P-type Metal Semiconductor oxide) field effect transistors (wherein the source and the drain regions are formed of p-type semiconductors) are formed in the upper layer whereas one or more NMOS (N-type Metal Semiconductor oxide) device field effect transistors (wherein the source and the drain regions are formed of n-type semiconductors) are formed in the lower layer. Although the semiconductor devices 1200 fabricated using the PMOS device in the upper layer is described according to the method 1100, it should be understood that that any type of the MOSFET device, such as, for example, an NMOS, can be used to form the transistor structure in the upper layer. Also, while the semiconductor devices 1200 fabricated using the NMOS device in the lower layer is described according to the method 1100, it should be understood that that any type of the MOSFET device, such as, for example, the PMOS, can be used to form the transistor structure in the lower layer.

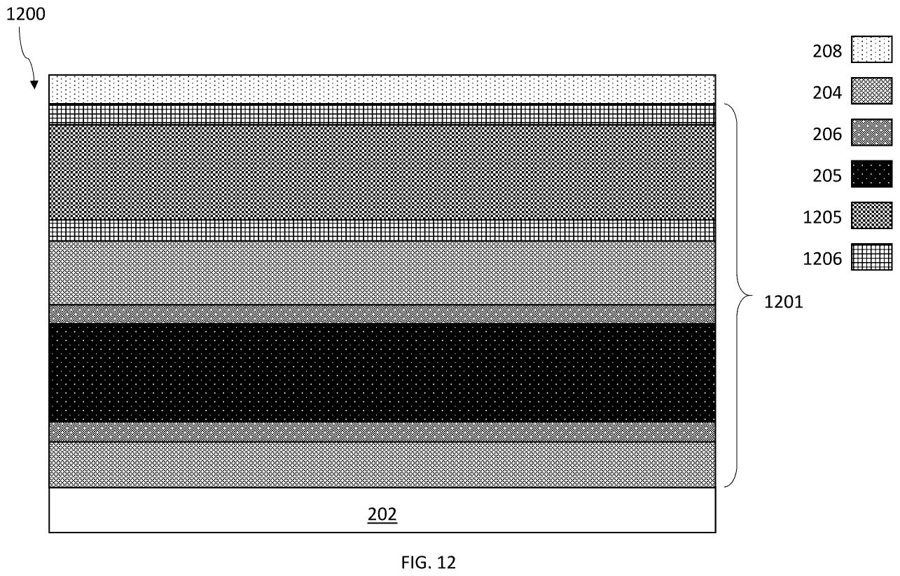

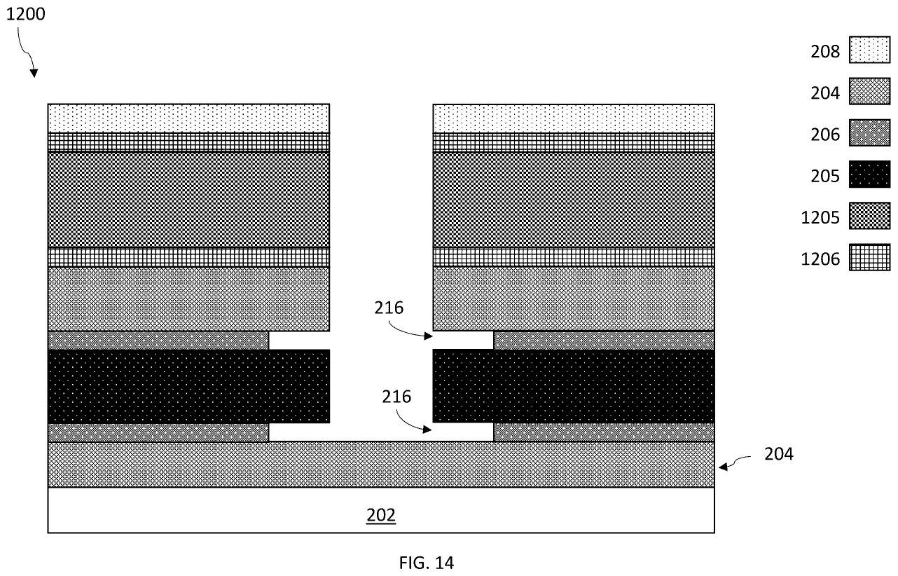

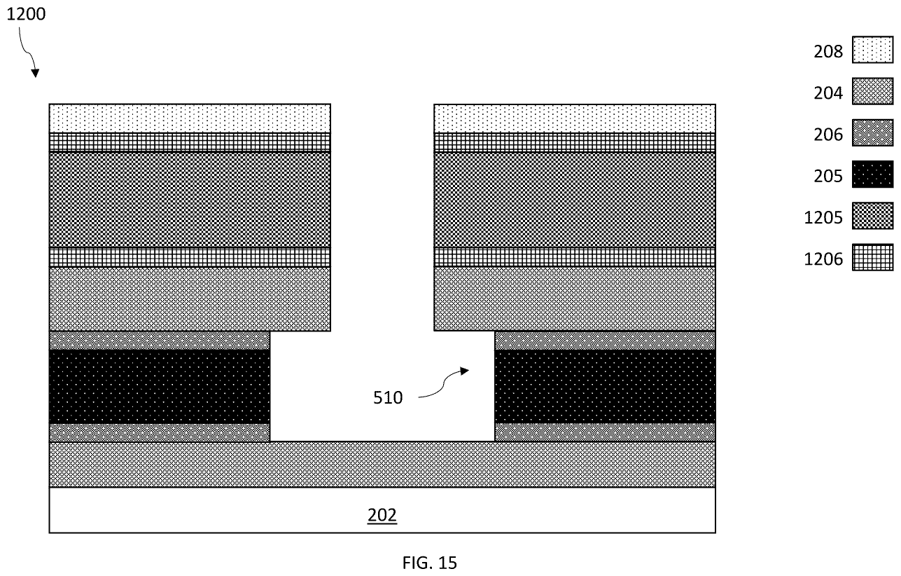

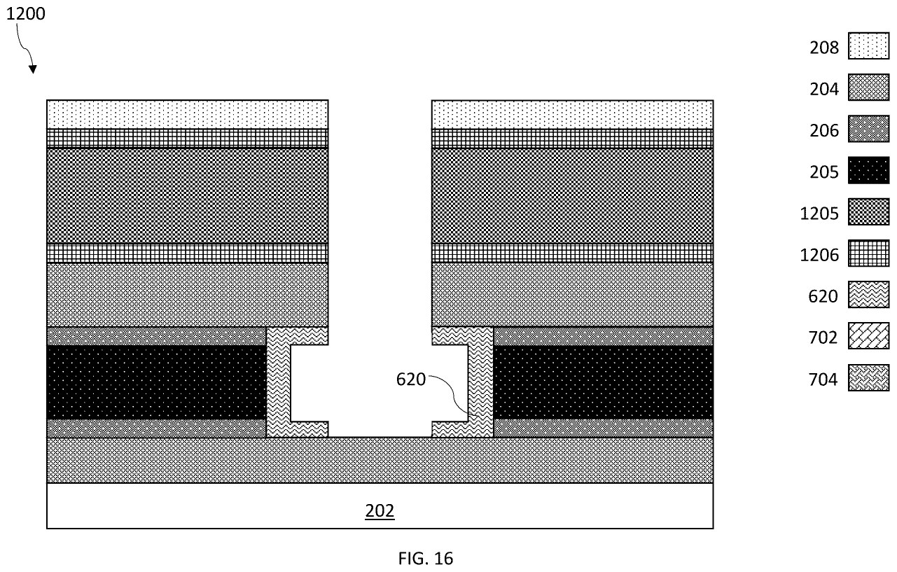

In various embodiments, some of the operations described above with respect to the method 100 (e.g., operations 1104 to 1110) may be reused in the method 1100, and thus, the following discussions will be focused on the different operations. Such (different) operations of the method 1100 may be associated with cross-sectional views of an example semiconductor device 1200 at various fabrication stages as shown in FIGS. 12 to 19, respectively, which will be discussed in further detail below. Further, some of the reference numerals used for the structures in the corresponding operations 104 through 116 (e.g., 202, 206, 205, 206, 208, 210, etc.) may be reused in FIGS. 12 to 19.

In brief overview, the method 1100 starts with operation 1102 of forming a stack of a number having at least two main layers each including a number of one or more dielectric materials (e.g., dielectric materials A through E), S/D metal materials, and/or semiconductor materials. The method 1100 proceeds to operation 1104 of patterning the stack. The method 1100 proceeds to operation 1106 of recessing the first S/D metal materials of a lower layer. The method 1100 proceeds to operation 1108 of forming recesses extending through the dielectric B material of the lower layer. The method 1100 proceeds to operation 1110 of depositing a first channel material in the lower layer. The method 1100 proceeds to operation 1112 of forming first high-k dielectric and first gate metal around the first channel material of the lower layer. The method 1100 proceeds to operation 1114 of forming a number of first dielectric spacers in the lower layer. The method 1100 proceeds to operation 1116 of depositing a first dielectric isolation in the lower layer.

Next, the method 1100 proceeds to operations 1118 through 1128 for the upper layer substantially repeating operations 1106 through 1116, but using different materials for certain operations (e.g., operations 1118 through 1124) so as to form in the upper layer transistor structures having a conductive type (e.g., PMOS devices) that is different from the conductive type of the lower layer (e.g., NMOS devices). For example, the method 1100 proceeds to operation 1118 of recessing the second S/D metal materials of an upper layer. The method 1100 proceeds to operation 1120 of forming recesses extending through the dielectric E material of the upper layer. The method 1100 proceeds to operation 1122 of depositing a second channel material in the upper layer. The method 1100 proceeds to operation 1124 of forming second high-k dielectric and second gate metal around the second channel material of the upper layer. The method 1100 proceeds to operation 1126 of forming a number of second dielectric spacers in the upper layer. The method 1100 proceeds to operation 1128 of depositing a second dielectric isolation in the upper layer.

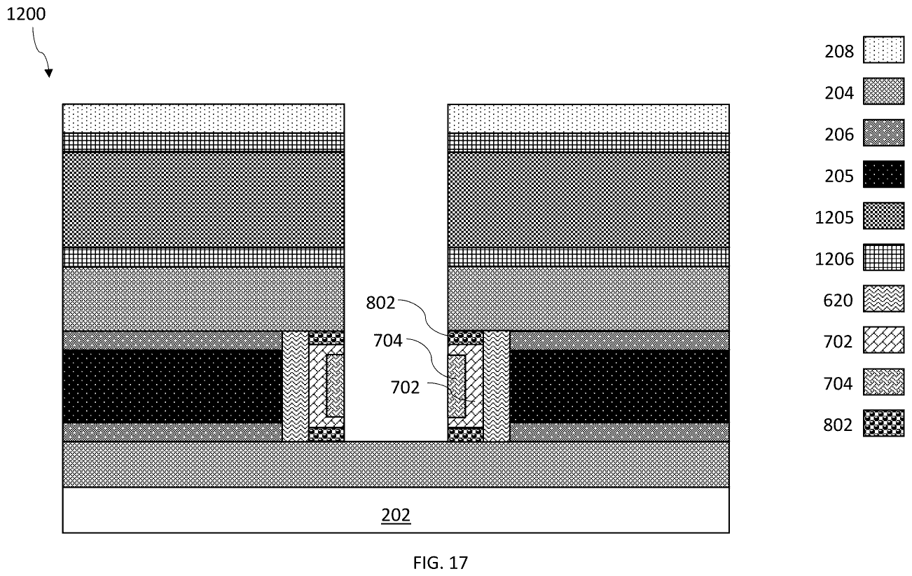

In various embodiments, several operations of the method 1100 are substantially similar to the operations of the method 100, except for the operations 1102, and 1112 through 1128. More specifically, the difference of operation 1102 from operation 102 is that in operation 1102, two different dielectric B and E materials 205 and 1205 as well as two different S/D metals 206 and 1206 are used for lower and upper layers, respectively. The difference of operations 1112-1116 from operations 112-116 is that in operations 1112-1116, transistor structures 804 are formed only in the lower layer. Another difference of operations 1112-1116 is that the first high-k dielectric 702, and the first gate metal 704 around the first longitudinal portion 622 of the semiconductor oxide material 620 of the lower layer are formed such that the first high-k dielectric 702 has a U-shape surrounding the first gate metal 704 as shown in FIG. 17.

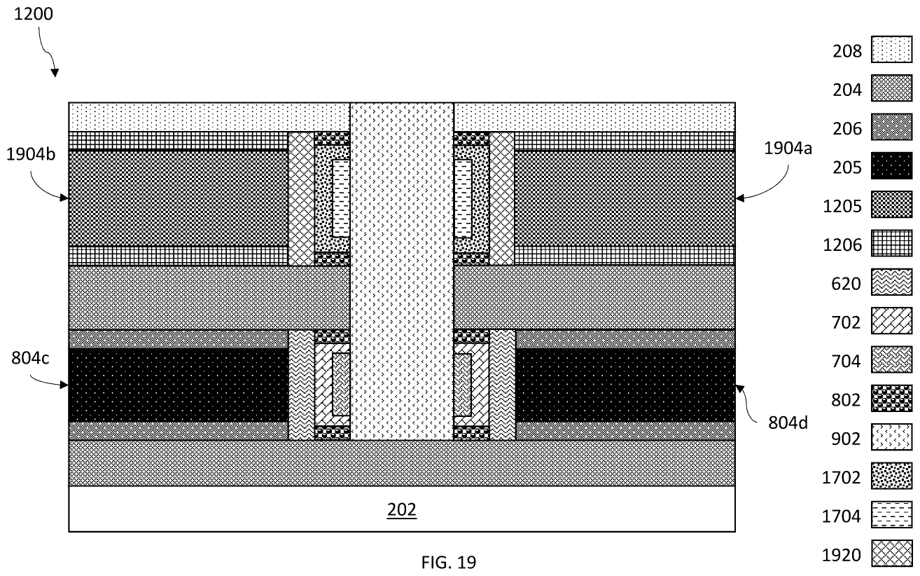

In various embodiments, operations 1118-1128 of the method 1100 for forming transistor structures 1904 (FIG. 19) in the upper layer of the stack are substantially similar to the operations 1106-1116 of the method 1100 for forming the transistor structures 804 in the lower layer of the stack, except that in the operations 1118-1128 the transistor structures 1904 of a different conductive type (e.g., PMOS-devices) than the transistor structures 804 (e.g., NMOS-devices) are formed. More specifically, the difference of operations 1118-1128 from operation 106-116 is that in operation 1118-1128, the upper layer of the semiconductor device 1200 includes the dielectric E material 1205, the second semiconductor oxide material 1620, the second S/D metal 1206, a second high-k dielectric 1702, and a second gate metal 1704, substituting the dielectric B material 205, the first semiconductor oxide material 620, the first S/D metal 206, the first high-k dielectric 702, and the first gate metal 704, respectively, as shown in FIG. 19.

The following cross-sectional views of the semiconductor device 1200 will be focused on the discussed differences with respect to the semiconductor device 200 formed according to the method 100.

Corresponding to operation 1102 of FIG. 11, FIG. 12 is a cross-sectional view of the semiconductor device 1100 in which a stack 1201 is formed having two layers including a number of dielectric materials, S/D metal, and semiconductor materials. In some embodiments, a stack 1201 is formed on a substrate 202, at one of the various stages of fabrication, in accordance with various embodiments. As shown in FIG. 12, the stack 1201, includes a number of dielectric materials of at least three different types: dielectric A generally denoted 204, dielectric B generally denoted 205, and dielectric E generally denoted 1205. Also, the stack 1201 includes a number of first and second source/drain (S/D) materials 206 and 1206, respectively, wherein the lower layer of the stack 1201 includes the dielectric B material 205 sandwiched between the two first S/D metal materials 206 and stacked on top of the dielectric A material 204. The upper layer of the stack 1201 includes the dielectric E material 1205 sandwiched between the two second S/D metal materials 1206 and stacked on top of the dielectric A material 204. Additionally, the stack 1201 may be overlaid by a cap layer 208. Although the stack 1201 has two layers in the illustrated embodiment of FIG. 12, it should be understood that the stack 1201 can include any number of the layers alternately stacked, while remaining within the scope of present disclosure.

In various embodiments, the dielectric A, B and E materials (204, 205 and 1205, respectively) can have an etching selectively with respect to one or more other materials formed next to itself, allowing the dielectric material A, B and/or E materials (204, 205 and/or 1205, respectively) to be selectively removed while keeping the adjacent materials substantially intact (which will be discussed in further detail below).

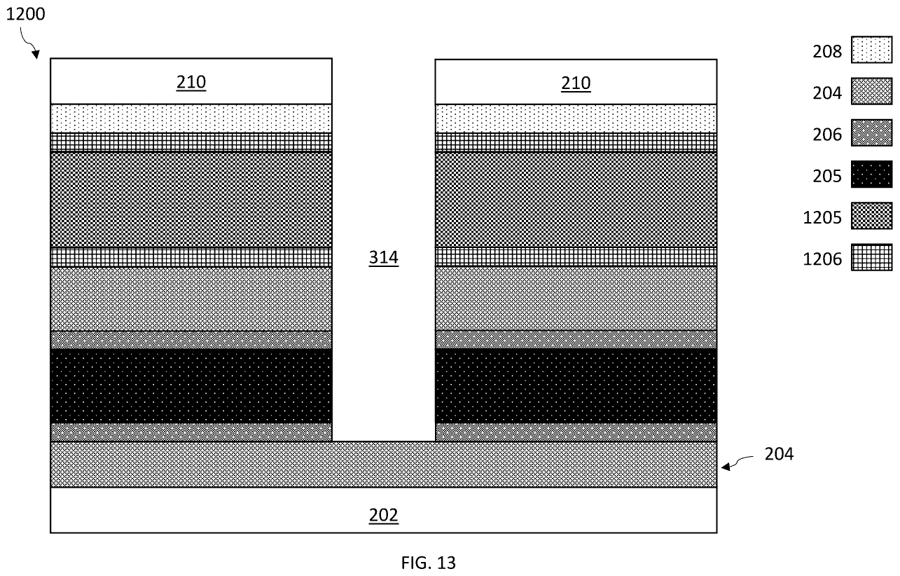

Corresponding to operations 1104-1110 of FIG. 11, FIGS. 13-16 are cross-sectional views of the semiconductor device 1200 in which, one or more first channel materials 620 are deposited in the lower layer, in accordance with various embodiments. The operations 1104-1110 are substantially similar to the operation 104-110 of the method 100, and thus, the description is not repeated.

Corresponding to operation 1112 of FIG. 11, FIG. 17 is a cross-sectional view of the semiconductor device 1200 including the first high-k dielectric 702 and the first gate metal 704. Operation 1112 of the method 1100 is similar to the operation 112 of the method 100, and thus, the description is not repeated.

Corresponding to operation 1114 of FIG. 11, FIG. 17 is a cross-sectional view of the semiconductor device 1200 in which a number of dielectric spacers 802 are formed in the lower layer to space apart the first channel material 620 from the first gate electrode 704, in accordance with various embodiments. The operation 1114 is substantially similar to the operation 114 of the method 100, and thus, the description is not repeated.

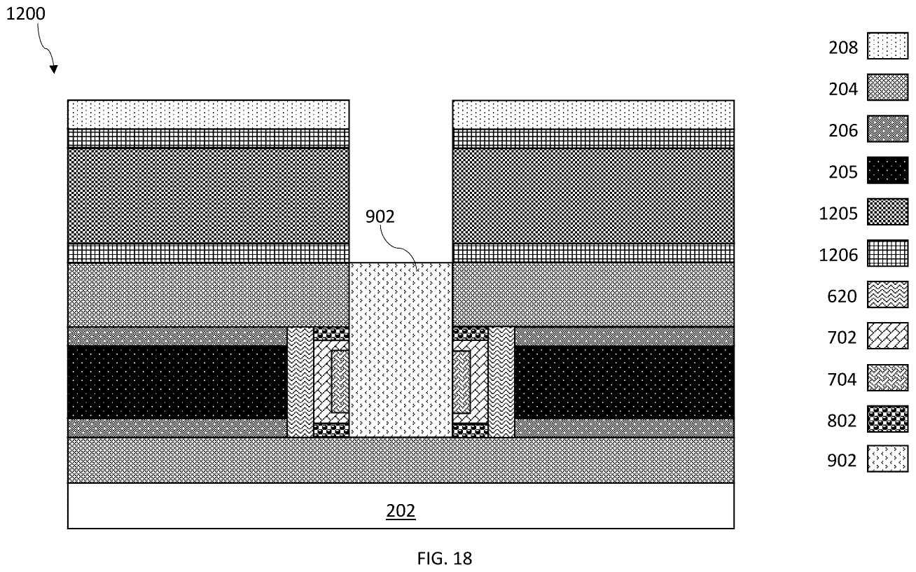

In the illustrative embodiment of FIG. 18, according to operation 1116, a first device isolation 902 is deposited in the lower layer of the semiconductor device 1200, in accordance with various embodiments. The operation 1116 is similar to the operation 116 of the method 100, except that in FIG. 18, the dielectric material of the first device isolation 902 may not fully fill up the main opening 314.

As mentioned above, operations 1118-1128 of the method 1100 for forming transistor structures 1904a-b (FIG. 19) in the upper layer of the stack are substantially similar to the operations 1106-1116 of the method 1100 for forming the transistor structures 804 in the lower layer of the stack, except that in the operations 1118-1128 the transistor structures 1904a-b of a different conductive type (e.g., PMOS-devices) than the transistor structures 804c-d (e.g., NMOS-devices) are formed. For example, in some embodiments, in operations 1118-1128 the following materials are used in the upper layer of the semiconductor device 1200, as shown in FIG. 19: the dielectric E material 1205 (instead of the dielectric material B in the lower layer of the semiconductor device 1200), the second channel material 1920 (instead of the first channel material 620 in the lower layer), the second S/D metal 1206 (instead of the first S/D metal 206 in the lower layer), the second high-k dielectric 1702 (instead of the first high-k dielectric 702 in the lower layer), and the second gate metal 1704 (instead of the first gate metal 704 in the lower layer). Other than this difference, operations 1118-1128 of the method 1100 are substantially similar to operations 1106-1116 of the method 1100, and thus, the description is not repeated. As a result of implementing method 1100, utilizing only one set of patternable layers (e.g., a photoresist mask), a pair of transistor structures 1904a and 1904b can be formed in the upper layer that have a different conductive type from a pair of transistor structures 804c and 804d that can be formed in the lower layer, as shown in FIG. 19.

Having now described some illustrative implementations and implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements and features discussed only in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

“Substrate” or “target substrate” may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation, and references to “an implementation,” “some implementations,” “an alternate implementation,” “various implementation,” “one implementation” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

The preceding description of the disclosed embodiments is provided to enable any person skilled in the art to make or use the embodiments described herein and variations thereof. Various modifications to these embodiments will be readily apparent to those skilled in the art, and the principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

While various aspects and embodiments have been disclosed, other aspects and embodiments are contemplated. The various aspects and embodiments disclosed are for purposes of illustration and are not intended to be limiting, with the true scope and spirit being indicated by the following claims.

What is claimed is:

1. A method, comprising:
forming a first pair of metal layers separated from each other with a first dielectric layer;
forming a first recess laterally extending into the first pair of metal layers and the first dielectric layer; and
forming a first transistor at the first recess.

2. The method of claim 1, further comprising:
lining the first recess with a first channel material; and
filling the first recess with a first gate structure.

3. The method of claim 1, further comprising:
forming a second pair of metal layers separated from each other with a second dielectric layer, wherein the second pair of metal layers are disposed next to the first pair of metal layers;
forming a third pair of metal layers separated from each other with a third dielectric layer, wherein the third pair of metal layers are disposed above the first pair of metal layers; and
forming a fourth pair of metal layers separated from each other with a fourth dielectric layer, wherein the fourth pair of metal layers are disposed above the second pair of metal layers.

4. The method of claim 3, further comprising:
forming a second recess laterally extending into the second pair of metal layers and the second dielectric layer;
forming a third recess laterally extending into the third pair of metal layers and the third dielectric layer;
forming a fourth recess laterally extending into the fourth pair of metal layers and the fourth dielectric layer;
forming a second transistor at the second recess;
forming a third transistor at the third recess; and
forming a fourth transistor at the fourth recess.

5. The method of claim 4, further comprising filling an opening between the first pair of metal layers and the second pair of metal layers and between the third pair of metal layers and the fourth pair of metal layers with a dielectric material to electrically isolate the first to fourth transistors from one another.

6. The method of claim 4, further comprising:
lining the second recess with a second channel material;
filling the second recess with a second gate structure;
lining the third recess with a third channel material;
filling the third recess with a third gate structure;
lining the fourth recess with a fourth channel material; and
filling the fourth recess with a fourth gate structure.

7. The method of claim 6, wherein each of the first to fourth channel materials includes a two-dimensional (2D) semiconductor material.

8. The method of claim 6, wherein each of the first to fourth channel materials includes a semiconductor oxide material.

9. The method of claim 4, wherein the first to fourth transistors have a same conductive type.

10. The method of claim 4, wherein the first and second transistor have a first conductive type, while the third and fourth transistors have a second, opposite conductive type.

11. A method, comprising:
exposing a first pair of metal layers separated from each other with a first dielectric layer and a second pair of metal layers separated from each other with a second dielectric layer, wherein the second pair of metal layers are laterally aligned with the first pair of metal layers, respectively;
exposing a third pair of metal layers separated from each other with a third dielectric layer and a fourth pair of metal layers separated from each other with a fourth dielectric layer, wherein the fourth pair of metal layers are laterally aligned with the second pair of metal layers, respectively;
removing exposed portions of the first pair of metal layers and the first dielectric layer and removing exposed portions of the second pair of metal layers and the second dielectric layer to form a first recess and a second recess, respectively;
removing exposed portions of the third pair of metal layers and the third dielectric layer and removing exposed portions of the fourth pair of metal layers and the fourth dielectric layer to form a third recess and a fourth recess, respectively;
forming a first transistor and a second transistor in the first and second recesses, respectively; and
forming a third transistor and a fourth transistor in the third and fourth recesses, respectively.

12. The method of claim 11, wherein removing exposed portions of the first pair of metal layers and the first dielectric layer and removing exposed portions of the second pair of metal layers and the second dielectric layer and removing exposed portions of the third pair of metal layers and the third dielectric layer and removing exposed portions of the fourth pair of metal layers and the fourth dielectric layer are concurrently performed, and the forming the first transistor and second transistor and forming the third transistor and fourth transistor are concurrently performed.

13. The method of claim 12, wherein the first to fourth transistors have a same conductive type.

14. The method of claim 11, wherein forming the first transistor and the second transistor is performed following removing exposed portions of the first pair of metal layers and the first dielectric layer and removing exposed portions of the second pair of metal layers and the second dielectric layer, and forming the third transistor and the fourth transistor is performed following removing exposed portions of the third pair of metal layers and the third dielectric layer and removing exposed portions of the fourth pair of metal layers and the fourth dielectric layer.

15. The method of claim 14, wherein the first and second transistors have a first conductive type, and the third and fourth transistors have a second, opposite conductive type.

16. The method of claim 11, wherein:
forming the first transistor and the second transistor further includes:
forming a first channel material and a second channel material in the first recess and the second recess, respectively; and
forming a first gate structure and a second gate structure in contact with vertically extending portions of the first channel material and the second channel material, respectively; and
forming the third transistor and the fourth transistor further includes:
forming a third channel material and a fourth channel material in the third recess and the fourth recess, respectively; and
forming a third gate structure and a fourth gate structure in contact with vertically extending of the third channel material and the fourth channel material, respectively.

17. The method of claim 16, wherein each of the first to fourth channel materials includes a two-dimensional (2D) semiconductor material.

18. The method of claim 16, wherein each of the first to fourth channel materials includes a semiconductor oxide material.

19. A device, comprising:
a pair of metal layers separated from each other with a dielectric layer;
a channel material vertically extending and having a first side in contact with the pair of metal layers; and
a gate structure vertically extending and in contact with a second side of the channel material.

20. The device of claim 19, further comprising a device isolation vertically extending and in contact with the gate structure.
